(19) United States
(12) Patent Application Publication
(10) Pub. No.: US 2026/0004809 A1
(43) Pub. Date: Jan. 1, 2026

(54) MAGNETIC RECORDING MEDIA WITH SMALL RECORDING GRAIN SIZES, HIGH ASPECT RATIO, AND METHODS OF FABRICATING SAME

(71) Applicant: Western Digital Technologies, Inc., San Jose, CA (US)

(72) Inventors: Hua Yuan, San Ramon, CA (US); Paul Christopher Dorsey, Los Altos, CA (US)

(21) Appl. No.: 18/757,954

(22) Filed: Jun. 28, 2024

(51) Int. Cl. G11B 5/73; C23C 14/08; C23C 14/34; G11B 5/851

(52) U.S. Cl. CPC G11B 5/7369; C23C 14/08; C23C 14/34; G11B 5/7375; G11B 5/7379; G11B 5/851

(57) ABSTRACT

Various apparatuses, systems, methods, and media are disclosed to provide a heat-assisted magnetic recording (HAMR) medium having small recording grain sizes with high aspect ratio. One example magnetic recording medium includes, a substrate, a heat sink layer on the substrate, an underlayer comprising MgO—TiO on the heat sink layer, an interfacial layer comprising TiN on the underlayer, a first nucleation layer on the interfacial layer and comprising FePt—Ag—X, wherein X is an oxide, a second nucleation layer on the first nucleation layer and comprising FePt—Ag—Y, wherein Y is an oxide or a nitride, and a magnetic recording layer on the second nucleation layer. In another example, the TiN is formed as a part of the underlayer rather than in the interfacial layer.

### FIELD

The disclosure relates, in some aspects, to magnetic recording media. More specifically, but not exclusively, the disclosure relates to magnetic recording media with small recording grain sizes, high aspect ratio, and methods for fabricating the media.

### INTRODUCTION

Magnetic storage systems, such as a hard disk drive (HDD), are utilized in a wide variety of devices in stationary and mobile computing environments. Examples of devices that incorporate magnetic storage systems include data center servers, desktop computers, portable notebook computers, portable hard disk drives, high-definition television (HDTV) receivers, television set top boxes, video game consoles, and portable media players.

A typical disk drive includes magnetic storage media in the form of one or more flat disks. The disks are generally formed of a few main substances, namely, a substrate material that gives it structure and rigidity, a magnetic recording layer that holds the magnetic impulses or moments that store digital data, and media overcoat and lubricant layers to protect the magnetic recording layer. The typical disk drive also includes a read head and a write head, generally in the form of a magnetic transducer which can sense and/or change the magnetic moments stored on the recording layer of the disks.

Heat assisted magnetic recording (HAMR) systems can increase the areal density of information recorded magnetically on various magnetic media. To achieve higher areal density for magnetic storage, smaller magnetic grain sizes, e.g., less than 6 nanometers (nm), may be required. In HAMR, high temperatures are applied to the media during writing to facilitate recording to small magnetic grains. The high temperatures may be achieved using a near field transducer that is coupled to a laser diode of a slider within a HAMR disk drive. Despite the benefits conferred by heat assisted magnetic recording, further improvements in areal density are desirable. One way to address this goal is to further reduce the magnetic recording grain sizes within the media. Aspects of the present disclosure are directed to addressing this challenge.

### SUMMARY

The following presents a simplified summary of some aspects of the disclosure to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present various concepts of some aspects of the disclosure in a simplified form as a prelude to the more detailed description that is presented later.

In one aspect, the disclosure provides a magnetic recording medium comprising: a substrate; a heat sink layer on the substrate; an underlayer comprising MgO—TiO on the heat sink layer; an interfacial layer comprising TiN on the underlayer; a first nucleation layer on the interfacial layer and comprising FePt—Ag—X, wherein X is an oxide; a second nucleation layer on the first nucleation layer and comprising FePt—Ag—Y, wherein Y is an oxide or a nitride; and a magnetic recording layer on the second nucleation layer.

In one aspect, the disclosure provides a magnetic recording medium comprising: a substrate; a heat sink layer on the substrate; a underlayer on the heat sink layer and comprising MgO—TiO (MTO) and TiN; a first nucleation layer on the underlayer and comprising FePt—Ag—X, wherein X is an oxide; a second nucleation layer on the first nucleation layer and comprising FePt—Ag—Y, wherein Y is an oxide or a nitride; and a magnetic recording layer on the second nucleation layer, wherein the underlayer comprises a first surface and a second surface closer to the first nucleation layer than the first surface; and wherein a concentration of the TiN in the underlayer is higher at the second surface than at the first surface.

In one aspect, the disclosure provides a method for fabricating a magnetic recording medium, the method comprising: providing a substrate; providing a heat sink layer on the substrate; providing an underlayer comprising MgO—TiO (MTO) on the heat sink layer; sputtering a first nucleation layer, comprising FePt—Ag—X where X is an oxide, on the underlayer using a N2 deposition gas, wherein N2 from the N2 deposition gas and Ti from the MTO of the underlayer form TiN; sputtering a second nucleation layer, comprising FePt—Ag—Y where Y is an oxide or a nitride, on the first nucleation layer; and providing a magnetic recording layer on the second nucleation layer.

In one aspect, the disclosure provides a magnetic recording medium formed using a process comprising: providing a substrate; providing a heat sink layer on the substrate; providing an underlayer comprising MgO—TiO (MTO) on the heat sink layer; sputtering a first nucleation layer, comprising FePt—Ag—X where X is an oxide, on the underlayer using a N2 deposition gas, wherein N2 from the N2 deposition gas and Ti from the MTO of the underlayer form TiN; sputtering a second nucleation layer, comprising FePt—Ag—Y where Y is an oxide or a nitride, on the first nucleation layer; and providing a magnetic recording layer on the second nucleation layer.

### BRIEF DESCRIPTION OF THE DRAWINGS

A more particular description is included below with reference to specific aspects illustrated in the appended drawings. Understanding that these drawings depict only certain aspects of the disclosure and are not therefore to be considered to be limiting of its scope, the disclosure is described and explained with additional specificity and detail through the use of the accompanying drawings.

FIG. 1 is a top schematic view of an exemplary data storage device configured for heat-assisted magnetic recording (HAMR) including a slider and a HAMR medium including small magnetic recording grains with a high aspect ratio, in accordance with an aspect of the disclosure.

FIG. 2 is a side schematic view of the exemplary slider and HAMR medium of FIG. 1 in accordance with an aspect of the disclosure.

FIG. 3 is a side schematic view of an exemplary HAMR medium that includes, among other layers, an underlayer and first and second nucleation layers that collectively provide the foundation for small magnetic recording grains with a high aspect ratio in the magnetic recording layers, in accordance with an aspect of the disclosure.

FIG. 4a is a sectional view of a comparative magnetic media that includes a histogram of the magnetic recording grain size/diameter for the comparative magnetic media.

FIG. 4b is a sectional view of an exemplary magnetic media that includes a histogram of the magnetic recording grain size/diameter for the exemplary magnetic media, in accordance with an aspect of the disclosure.

FIG. 4c is a table illustrating a comparison of various media characterization parameters for the exemplary magnetic media of FIG. 4b and the comparative magnetic media of FIG. 4a, in accordance with an aspect of the disclosure.

FIG. 5 illustrates multiple cross-sectional views of the magnetic recording grains of the comparative magnetic media of FIG. 4a at various resolutions or sections that show undesirable characteristics such as short or defective grains.

FIG. 6 illustrates multiple cross-sectional views of the magnetic recording grains of the exemplary magnetic media of FIG. 4b at various resolutions or sections that show desirable characteristics such as uniform grains with small diameter, in accordance with an aspect of the disclosure.

FIG. 7 illustrates multiple cross-sectional views of the exemplary magnetic recording media showing the concentrations of select material elements contained therein, in accordance with an aspect of the disclosure.

FIG. 8 is a flowchart of an exemplary process for fabricating a HAMR medium that includes small magnetic recording grains with a high aspect ratio, in accordance with an aspect of the disclosure.

FIG. 9 is a flowchart of another exemplary process for fabricating a HAMR medium that includes small magnetic recording grains with a high aspect ratio, in accordance with an aspect of the disclosure.

### DETAILED DESCRIPTION

In the following detailed description, reference is made to the accompanying drawings, which form a part thereof. In addition to the illustrative aspects, aspects, and features described above, further aspects, aspects, and features will become apparent by reference to the drawings and the following detailed description. The description of elements in each figure may refer to elements of proceeding figures. Like numbers may refer to like elements in the figures, including alternate aspects of like elements.

The disclosure relates in some aspects to various apparatuses, systems, methods, and media for providing a magnetic recording medium such as a Heat-Assisted Magnetic Recording (HAMR) medium that can, among other features, provide for optimized or at least improved magnetic performance within the HAMR medium. Note that HAMR is a type of Energy-Assisted Magnetic Recording (EAMR), which is a broader term that covers HAMR as well as Microwave Assisted Magnetic Recording (MAMR). At least some aspects of the present disclosure are not limited to HAMR and are applicable to EAMR.

As mentioned in the introduction above, further improvements in areal density for magnetic storage is a challenge. One way to address this goal is to further reduce the magnetic recording grain sizes within the media. As used herein, “grain size” means the diameter of columnar shaped magnetic recording grains formed in one or more magnetic recording layers of a magnetic medium. Aspects of the present disclosure are directed to designing magnetic recording media with smaller magnetic recording grains with a high aspect ratio (e.g., ratio of grain height to grain diameter). In one aspect, a magnetic recording media is provided with an underlayer including MgO—TiO (MTO) and first and second nucleation layers that set a template for subsequent magnetic recording layers (MRLs) having small magnetic recording grains with a high aspect ratio. The first nucleation layer may be made of FePt—Ag-oxide, and sputter deposited on the MTO underlayer using a nitrogen (N2) deposition gas. The N2 can react and/or bond with the Ti from the underlayer to form TiN (e.g., an interfacial layer made of TiN). The second nucleation layer may be made of FePt—Ag-oxide/nitride, and sputter deposited on the first nucleation layer using an argon (Ar) deposition gas. One or more magnetic recording layers are disposed on top of the second nucleation layer. The resulting magnetic media shows superior performance characteristics, including smaller diameter grains (e.g., roughly 17% reduction) than comparative recording media. More specifically, the diameter of the grains is reduced by about 17% and the aspect ratio is increased by about 14.7%. As a result, the areal density is expected to be increased accordingly.

### ILLUSTRATIVE EXAMPLES AND EMBODIMENTS

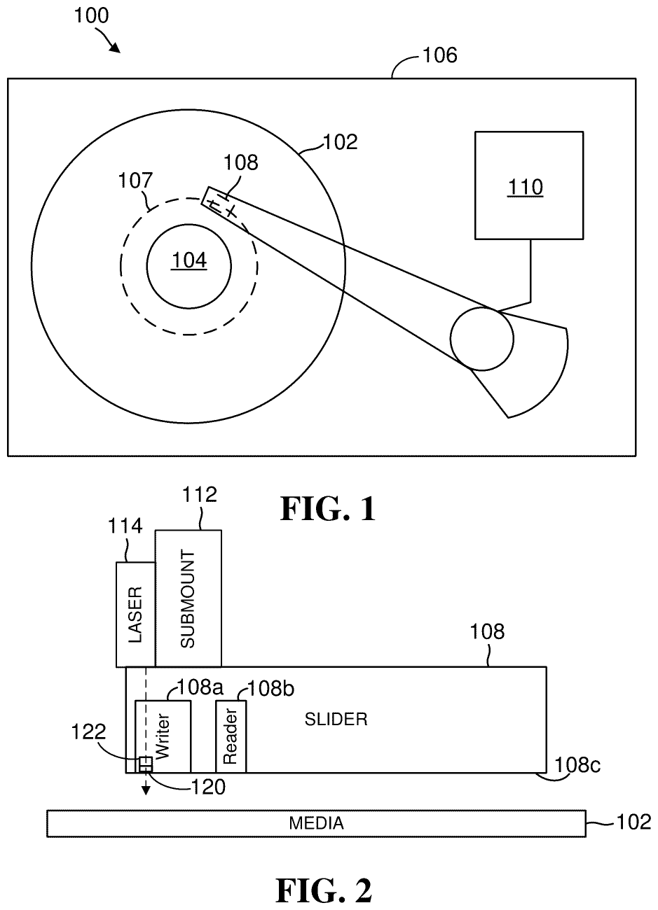

FIG. 1 is a top schematic view of an exemplary data storage device configured for heat-assisted magnetic recording (HAMR) including a slider and a HAMR medium including small magnetic recording grains with a high aspect ratio, in accordance with an aspect of the disclosure. The laser (not visible in FIG. 1 but see 114 in FIG. 2) is positioned with a magnetic head/slider 108. Disk drive 100 may include one or more disks/media 102 to store data. Disk/media 102 resides on a spindle assembly 104 that is mounted to a drive housing 106. Data may be stored along tracks in the magnetic recording layer of disk 102. The reading and writing of data is accomplished with the head 108 (slider) that may have both read and write elements (108a and 108b). The write element 108a is used to alter the properties of the magnetic recording layer of disk 102 and thereby write information thereto. In one aspect, head 108 may have magneto-resistive (MR) based elements, such as tunnel magneto-resistive (TMR) elements for reading, and a write pole with coils that can be energized for writing. In operation, a spindle motor (not shown) rotates the spindle assembly 104, and thereby rotates the disk 102 to position the head 108 at a particular location along a desired disk track 107. The position of the head 108 relative to the disk 102 may be controlled by the control circuitry 110 (e.g., a microcontroller). It is noted that while an exemplary HAMR system is shown, at least some aspects of the disclosure may be used in other HAMR or EAMR magnetic data recording systems or in non-HAMR or non-EAMR magnetic data recording systems, including shingle-written magnetic recording (SMR) media, perpendicular magnetic recording (PMR) media, or microwave assisted magnetic recording (MAMR) media.

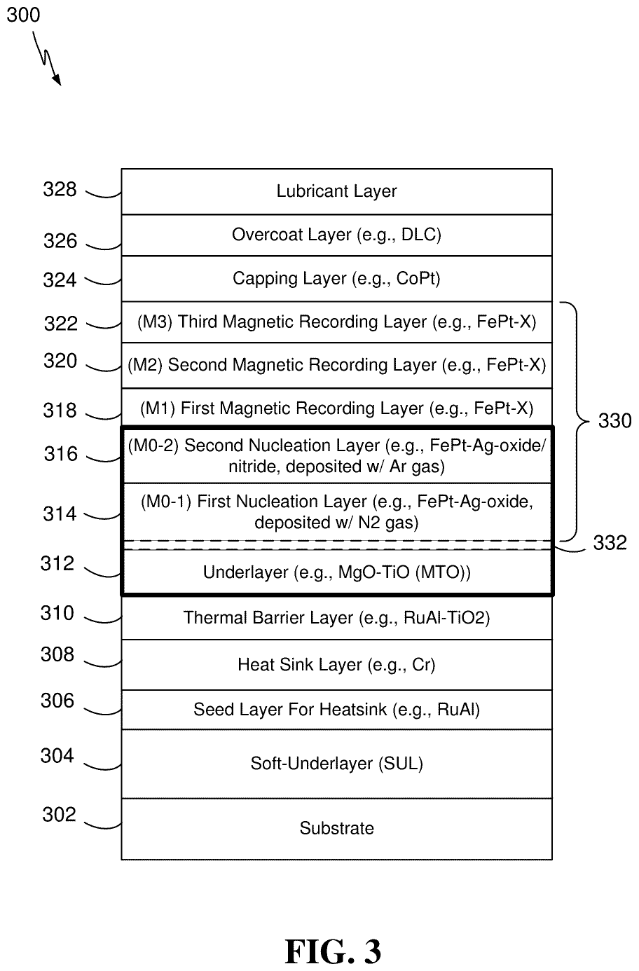

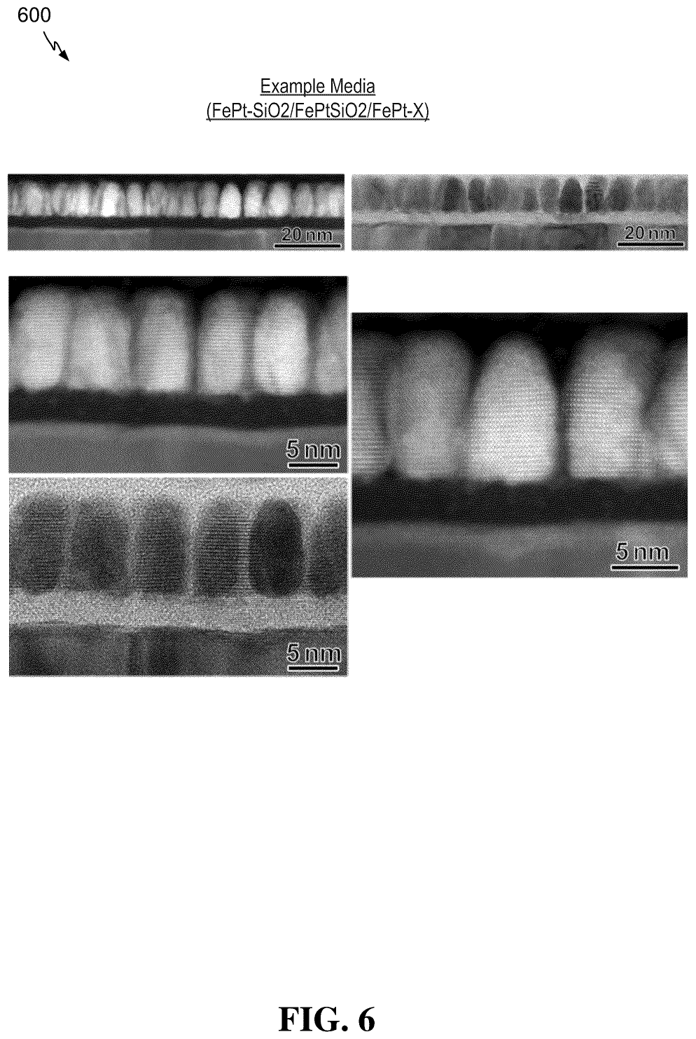

FIG. 2 is a side schematic view of the slider 108 and magnetic recording medium 102 of FIG. 1. The magnetic recording medium 102 includes small recording grains within the magnetic recording layer (layers not visible in FIG. 2 but see FIGS. 3 and 6). The slider 108 may include a sub-mount 112 attached to a top surface of the slider 108. The laser 114 may be attached to the sub-mount 112, and possibly to the slider 108. The slider 108 includes a write element (e.g., writer) 108a and a read element (e.g., reader) 108b positioned along an air bearing surface (ABS) 108c of the slider for writing information to, and reading information from, respectively, the media 102. In other aspects, the slider may also comprise a layer of Si or Si cladding 120. This layer is optional.

In operation, the laser 114 is configured to generate and direct light energy to a waveguide (e.g., along the dashed line) in the slider which directs the light to a near field transducer (NFT) 122 near the air bearing surface (e.g., bottom surface) 108c of the slider 108. Upon receiving the light from the laser 114 via the waveguide, the NFT 122 generates localized heat energy that heats a portion of the media 102 within or near the write element 108a, and near the read element 108b. The anticipated recording temperature is in the range of about 350° C. to 400° C. In the aspect illustrated in FIG. 2, the laser directed light is disposed within the writer 108a and near a trailing edge of the slider. In other aspects, the laser directed light may instead be positioned between the writer 108a and the reader 108b. FIGS. 1 and 2 illustrate a specific example of a HAMR system. In other examples, the magnetic recording medium 102 can be used in other suitable HAMR systems (e.g., with other sliders configured for HAMR).

FIG. 3 is a side schematic view of an exemplary HAMR medium 300 that includes, among other layers, an underlayer and first and second nucleation layers that collectively provide the foundation for small magnetic recording grains with a high aspect ratio in the magnetic recording layers, in accordance with an aspect of the disclosure. The HAMR medium 300 of FIG. 3 has a stacked structure with a substrate 302 at a bottom/base layer, a soft underlayer (SUL) 304 on the substrate 302, a seed layer 306 for a heat sink layer on the SUL 304, a heat sink layer 308 (e.g., of Cr) on the seed layer 306 for the heat sink layer, a thermal barrier layer 310 (e.g., RuAl—TiO2) on the heat sink layer 308, an underlayer 312 (e.g., MgO—TiO or MTO) on the thermal barrier layer 310, a first nucleation layer (“M0-1”) 314 (e.g., FePt—Ag-oxide sputter deposited using N2 gas) on the underlayer 312, a second nucleation layer (“M0-2”) 316 (e.g., FePt—Ag-oxide/nitride sputter deposited using Ar gas) on the first nucleation layer 314, a first magnetic recording layer (“M1”) 318 (e.g., FePt—X where X is a suitable segregant) on the second nucleation layer 316, a second magnetic recording layer (“M2”) 320 (e.g., FePt—X where X is a suitable segregant) on the first magnetic recording layer 318, a third magnetic recording layer (“M3”) 322 (e.g., FePt—X where X is a suitable segregant) on the second magnetic recording layer 320, a capping layer 324 (e.g., CoFe or CoPt and one or more segregants) on the third MRL 322, an overcoat layer 326 (e.g., made of diamond like carbon (DLC) or other suitable materials) on the capping layer 324, and a lubricant layer 328 on the overcoat layer 326. In one aspect, the first and second nucleation layers 314 and 316 and each of MRLs 318-322 can collectively be referred to as an MRL structure 330.

In some aspects, the HAMR medium 300 can include additional layers. In one example, the HAMR medium 300 also includes an adhesion layer (which may be formed, e.g., of NiTa, CrTi, or the like) on the substrate 302 and under the SUL 304. The adhesion layer may be used to reduce delamination of layers or films deposited over the adhesion layer.

The media 300 may be fabricated using one or more material deposition techniques for depositing each of the layers on the substrate 302. In one aspect, the underlayer 312 and first and second nucleation layers (314, 316) may be of particular interest. More specifically, use of MTO for the underlayer 312 may have advantages over other underlayer or seed layer materials such as MgO. That is, an underlayer made of MgO may require complex and overly time-consuming deposition processes such as radio frequency (RF) sputtering. The use of MTO on the other hand, and more specifically because of the improved conductivity of MTO (as compared to MgO), may allow for the use of direct current (DC) sputtering, which can be faster and more efficient than the RF sputtering. Thus, the use of MTO may provide fabrication efficiencies. At the same time, Ti from the MTO can sometimes migrate to other layers, such as the MRLs or elsewhere, and cause problems in recording performance (e.g., degrade recording performance). Applicants have discovered that the use of N2 gas (e.g., pure or substantially pure N2 (e.g., not more than 5% impurities)) during the sputter deposition of the first nucleation layer (M0-1) 314 causes the formation of TiN, which appears to provide several beneficial performance results in the media. Those performance results (smaller grains with high aspect ratio) are briefly described above and will be described in greater detail below.

In one aspect, the TiN tends to form/concentrate at the top surface of the MTO underlayer 312. For example, the underlayer 312 includes a first surface (e.g., bottom surface) and a second surface (e.g., top surface) closer to the first nucleation layer 314 than the first surface, and a concentration of the TiN in the underlayer 312 is higher at the second surface than at the first surface. In one aspect, the TiN may even effectively form a TiN layer 332 as shown in FIG. 3 (e.g., an interfacial layer made of TiN) between the underlayer 312 and the first nucleation layer 314. In another aspect, it may be that the TiN forms/concentrates at or near the bottom surface of the first nucleation layer 314. In any case, the resulting media structure shows improved grain structure over comparative media structures and thereby provides or is expected to provide improved magnetic recording performance.

As noted above, the first nucleation layer 314 may be made of FePt—Ag—X where X is an oxide. Suitable oxides include SiO2, TiO2, Cr2O3, ZrO2, Al2O3, Fe2O3, Ta2O5, or the like. In one example, X is SiO2. In one aspect, the first nucleation layer 314 may include some amount of embedded N2, from the sputter deposition of the layer. In one aspect, the first nucleation layer (M0-1) 314 composition is 34Fe-34 Pt-10.5Ag-21.5 (SiO2) (mol %). The Ag may range from 0.1 mol % to 15 mol %, and the SiO2 may range from 0.5 mol % to 21.5 mol %.

The second nucleation layer 316 may be made of FePt—Ag—Y where Y is an oxide or a nitride. Suitable Y oxides include SiO2, TiO2, Cr2O3, ZrO2, Al2O3, Fe2O3, Ta2O5, or the like. Suitable Y nitrides include Si3N4, TiN, CrN, TaN, ZrN, VN, or the like. In one example, Y is SiO2. The use of an oxide or a nitride in the second nucleation layer (M0-2) 316 is believed to contribute to the small recording grains in the MRLs (318, 320, 322) of the media structure. In one aspect, the FePt in the second nucleation layer (M0-2) 316 has a range of 15 to 45 mol. %. In one aspect, the oxide and/or nitride in the second nucleation layer (M0-2) 316 has a range of 0.5 to 70 vol. %. In one aspect, the Ag in the second nucleation layer (M0-2) 316 has a range of 0.1 to 12 mol. %. In one aspect, the second nucleation layer 316 may be made of FePt-10.5Ag-21.5SiO2, or minor deviations from those percentages (e.g., 5-10% deviation). In one aspect, for example, the second nucleation layer 316 may be made of 34Fe-34 Pt-10.5Ag-21.5 (SiO2) (mol %). The Ag may range from 0.1 mol % to 15 mol %, and the SiO2 may range from 0.5 mol % to 21.5 mol %.

In some examples, the substrate 302 has an outer diameter (i.e., OD) of about 97 mm and a thickness of about 0.5 mm. In other examples, the OD may be 95 mm or 95.1 mm. (Generally speaking, such disks are all referred to as “3.5 inch” disks.) In some aspects, the substrate 302 may be made of one or more materials such as an Al alloy, NiP-plated Al, glass, glass ceramic, and/or combinations thereof.

In some aspects, the SUL 304 can be made of one or more materials, such as Co, Fe, Mo, Ta, Nb, B, Cr, or other soft magnetic materials, or combinations thereof. The SUL 304 may include an amorphous compound or combination of Co and Fe (e.g., a CoFe alloy) with the addition of one or more elements from Mo, Nb, Ta, W, and B. The SUL 304 may be configured to support magnetization of the magnetic recording layer structure (e.g., layers 314-322 or just layers 318-322) during data storage operations. More specifically, the SUL 304 may be configured to provide a return path for a magnetic field applied during a write operation.

In some aspects, the heat sink seed layer 306 is used to create a growth template for the subsequently deposited films including the heatsink layer 308. Functional goals for the (heatsink) seed layer 306 include small grain size and good crystallographic texture, both of which may be desirable for good media recording performance. In one aspect, the heat sink seed layer 306 is made of RuAl or other suitable materials known in the art.

In some aspects, the heat sink layer 308 can be made of one or more materials such as Cr, as shown, or Ag, Al, Au, Cu, Mo, Ru, W, CuZr, MoCu, AgPd, CrRu, CrV, CrW, CrMo, CrNd, NiAl, NiTa, combinations thereof, and/or other suitable materials known in the art.

In some aspects, the thermal barrier layer 310 may be deposited directly on the heat sink layer 308 to provide thermal resistance to the heatsink layer and/or a thermal gradient in the media to assist writing to the media. The thermal barrier layer 310 may be etched to reduce roughness. In one aspect, the thermal barrier layer 310 is made of RuAl—TiO2 or other suitable materials known in the art.

In some aspects, the underlayer 312 is provided as an underlayer or a seed layer for the nucleation layers 314 and 316 and the MRLs (318-322) to assist in nucleation so as to permit proper crystal growth within the MRLs so that the MRLs will have good crystallographic texture with small grains. As noted above, the underlayer 312 may be made of MgO—TiO (MTO). In one aspect, the underlayer may be implemented using multiple layers (e.g., multiple MTO layers or combinations of MgO layers and MTO layers).

The suitable materials for the first and second nucleation layers are described above.

As illustrated, the MRL structure 330 includes five magnetic recording layers (314 (M0-1), 316 (M0-2), 318 (M1), 320 (M2), 322 (M3)). In some aspects, the M1-M3 sub-layers of the MRL structure 330 may be made of FePt or an alloy selected from FePtX, where X is a material selected from an oxide, Cu, Ni, and combinations thereof. In some aspects, these sub-layers of the MRL structure 330 may be made of a CoPt alloy. In some examples, the sub-layers of the MRL structure 330 may include one or more of L10 FePt, FePd, CoPt, or MnAl, or possibly a CoPt/CoPd multilayer alloy, each layer having a predetermined thickness, granular structure, small grain size, desired uniformity, high coercivity, high magnetic flux, and good atomic ordering, as would be appropriate for HAMR media. Other additive elements may be added to the aforementioned MRL structure 330 including, e.g., Ag, Au, Cu, or Ni. In other embodiments, there may be a different number of MRLs other than the five MRLs in MRL structure 330. In one aspect, M1 is made of FePtAgCu(BN), M2 is made of FePt(BN)C, and M3 is made of FePt(BN)(SiO2).

In some aspects, the capping layer 324 may be made of Co, CoPt, CoFe, or CoPd. In one example, the capping layer 324 can be a multi-layer structure having a layer including Co and Pt/Pd. In some embodiments, the capping layer 324 may be made of specific combinations of materials, for example, Co/Pt, Co/Au, Co/Ag, Co/Al, Co/Cu, Co/Ir, Co/Mo, Co/Ni, Co/Os, Co/Ru, Co/Ti, Co/V, Fe/Ag, Fe/Au, Fe/Cu, Fe/Mo, Fe/Pd, Ni/Au, Ni/Cu, Ni/Mo, Ni/Pd, Ni/Re, etc. In additional examples, multilayer layer materials include any combination of Pt and Pd (e.g., alloys), or any of the following elements, alone or in combination: Au, Ag, Al, Cu, Ir, Mo, Ni, Os, Ru, Ti, V, Fe, Re, and the like.

In some aspects, the overcoat layer 320 may be made of carbon (e.g., diamond like carbon or DLC). In one aspect, the lubricant layer 322 may be made of a polymer-based lubricant.

Note that the terms “above,” “below,” “on,” and “between” as used herein refer to a relative position of one layer with respect to other layers. As such, one layer deposited or disposed on, above, or below another layer may be directly in contact with the other layer or may have one or more intervening layers. Moreover, one layer deposited or disposed between layers may be directly in contact with the layers or may have one or more intervening layers.

Insofar as the processes described herein are concerned, the processes can in some cases perform the sequence of actions in a different order. In another aspect, the process can skip one or more of the actions. In other aspects, one or more of the actions are performed simultaneously. In some aspects, additional actions can be performed. Unless otherwise indicated, the deposition of at least some of the layers can be performed using any of a variety of deposition processes or sub-processes, including, but not limited to physical vapor deposition (PVD), sputter deposition and ion beam deposition, plasma enhanced chemical vapor deposition (PECVD) and other forms of chemical vapor deposition (CVD), low pressure chemical vapor deposition (LPCVD) and atomic layer chemical vapor deposition (ALCVD). In other aspects, other suitable deposition techniques known in the art might also be used.

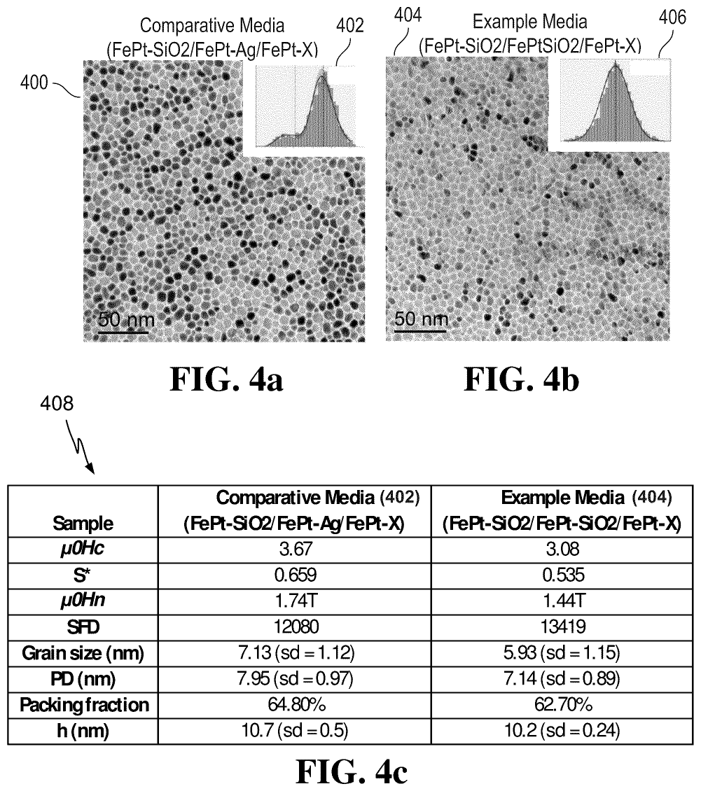

FIG. 4a is a sectional view of a comparative magnetic media 400 that includes a histogram 402 of the magnetic recording grain size/diameter for the comparative magnetic media. This sectional view was generated using transmission electron microscopy (TEM) and shows an area of the magnetic recording media 400 at 50 nanometers (nm) by 50 nm. The comparative magnetic media 400 has a similar structure to that of the media of FIG. 3 except that M0-1, M0-2, and M1 are replaced with FePt—SiO2, FePt—Ag, and FePt—X (where X is an oxide such as SiO2), respectively. The histogram 402 shows a bimodal grain distribution for the comparative magnetic media 400 where, instead of having a predominance of a single grain size (e.g., something akin to a uniform grain size), there are two peaks representing different grain sizes, where one is much larger than the other. This bimodal grain distribution is undesirable in that it does not represent uniform grain size distribution, and as subsequent experimental data analysis will show magnetic recording performance is negatively impacted.

FIG. 4b is a sectional view of an exemplary magnetic media 404 that includes a histogram 406 of the magnetic recording grain size/diameter for the exemplary magnetic media, in accordance with an aspect of the disclosure. This sectional view was generated using TEM and shows an area of the magnetic recording media 404 at 50 nm by 50 nm. The exemplary magnetic media 404 has the same structure to that of the media of FIG. 3 with specific selections for some variable materials such that M0-1 (314) is made of FePt—SiO2, M0-2 (316) is made of FePt—SiO2, and M1 (318) is made of FePt—X (where X is AgCu(BN)), respectively. In one aspect, for example, the first nucleation layer (M0-1) composition in FIG. 4a is 34Fe-34 Pt-10.5Ag-21.5 (SiO2) (mol %), and the second nucleation layer (M0-2) composition in FIG. 4a is 34Fe-34 Pt-10.5Ag-21.5 (SiO2) (mol %). In one aspect, M1 is made of FePtAgCu(BN), M2 is made of FePt(BN)C, and M3 is made of FePt(BN)(SiO2). The histogram 406 shows a uniform grain distribution for the exemplary magnetic media 404 having a predominance of a single grain size, resulting in a single peak. This uniform grain distribution is desirable, and as subsequent experimental data analysis will show magnetic recording performance is positively impacted.

FIG. 4c is a table 408 illustrating a comparison of various media characterization parameters for the exemplary magnetic media of FIG. 4b and the comparative magnetic media of FIG. 4a, in accordance with an aspect of the disclosure. These media characterization parameters include μ0Hc (coercivity), S* (degree of hysteresis or slope of magnetic loops), μ0Hn (nucleation field or field strength needed to reverse a grain's magnetization), SFD (the dispersion of the magnetic fields required to reverse the magnetization direction of FePt grains), grain size (diameter) in nm, pitch distance (PD, distance from one grain center to adjacent grain center) in nm, packing fraction (grain area versus entire area of layer) in percent, and height (h or grain height) in nm. The “sd” parameter is the standard deviation of the respective value.

One key take away from the table 408 is the reduced grain size (diameter), which is 5.93 nm for the example magnetic media 404 of FIG. 4b versus 7.13 nm for the comparative media 400 of FIG. 4a. Thus, the diameter of the grains in the exemplary media 404 is reduced by about 17% and the aspect ratio (height divided by diameter) is increased by about 14.7%, as compared to the comparative media 400.

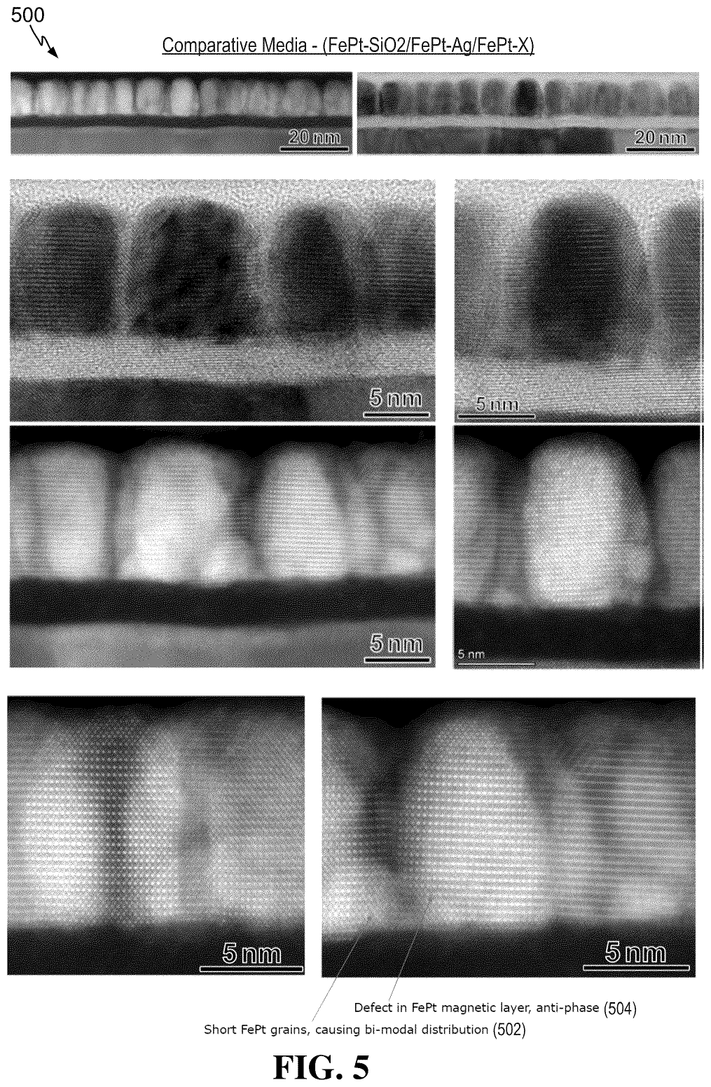

FIG. 5 illustrates multiple cross-sectional views 500 of the magnetic recording grains of the comparative magnetic media of FIG. 4a at various resolutions or sections that show undesirable characteristics such as short or defective grains. In particular, the short grains 502 that may cause the bimodal grain distribution are shown in the lower right image. Also, defective grains 504 that are anti-phase are shown in the lower right image. In one aspect, the cross-sectional views in FIG. 5 were generated using TEM.

FIG. 6 illustrates multiple cross-sectional views of the magnetic recording grains of the exemplary magnetic media of FIG. 4b at various resolutions or sections that show desirable characteristics such as uniform grains with small diameter, in accordance with an aspect of the disclosure. As shown in FIG. 6, the magnetic recording grains are well defined, uniform, and lack the type of short grains or defective grains shown in FIG. 5 for the comparative magnetic media. In one aspect, the cross-sectional views in FIG. 6 were generated using TEM.

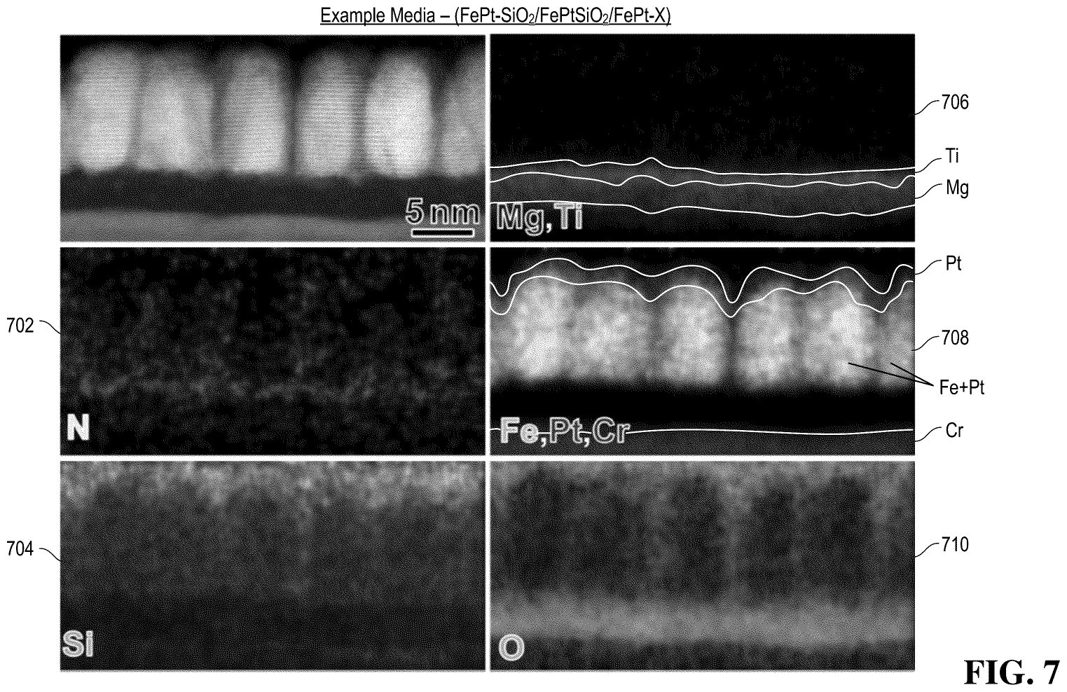

FIG. 7 illustrates multiple cross-sectional views of the exemplary magnetic recording media showing the concentrations of select material elements contained therein, in accordance with an aspect of the disclosure. For example, the image/view 702 shows the areas of concentration for N in the exemplary magnetic recording media (e.g., the media of FIGS. 3, 4b, and 6), where the lighter color indicates the locations of the N. The image/view 704 shows the areas of concentration for Si in the exemplary magnetic recording media, where the lighter color indicates the locations of the Si. The image/view 706 shows the areas of concentration for Mg and Ti in the exemplary magnetic recording media (note that white color lines have been superimposed on the image to show the areas of concentration for each of Mg and Ti). The image/view 708 shows the areas of concentration for Fe, Pt, and Cr in the exemplary magnetic recording media (note that white color lines have been superimposed on the image to show the areas of concentration for each of Cr, FePt grains, and Pt concentrated on top areas of grains). The image/view 710 shows the areas of concentration for O in the exemplary magnetic recording media, where the lighter color indicates the locations of the O. From images 702, 706 and 708, it can be seen that the N and Ti effectively concentrate at the area just below the grains. As discussed above, the TiN may form during the deposition of M0-1 at or near the top surface of the MTO underlayer, and these images 702 and 706 confirm that observation.

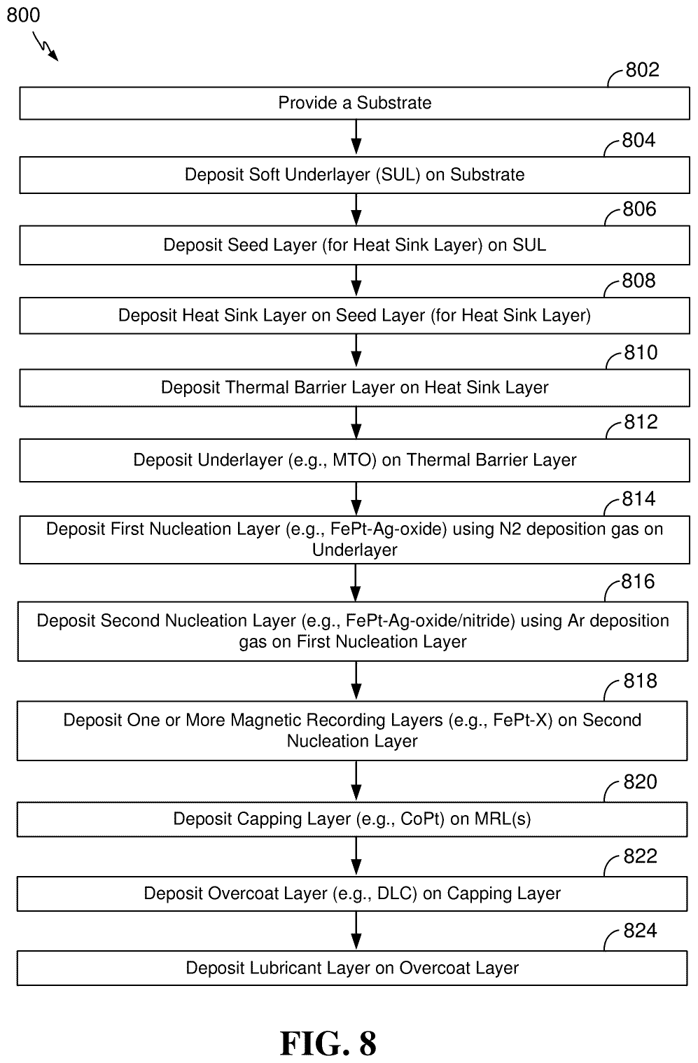

FIG. 8 is a flowchart of an exemplary process 800 for fabricating a HAMR medium that includes small magnetic recording grains with a high aspect ratio, in accordance with an aspect of the disclosure. In one aspect, the process 800 can be used to fabricate any of the HAMR media described above, including, for example, HAMR mediums 102, 300, 404, and 600.

At block 802, the process provides a substrate (e.g., 302). At block 804, the process deposits a soft magnetic underlayer (SUL, e.g., 304) on the substrate. At block 806, the process deposits a seed layer (e.g., 306) for a subsequent heat sink layer on the SUL. At block 808, the process deposits a heat sink layer (e.g., 308) on the seed layer for the heat sink layer. At block 810, the process deposits a thermal barrier layer (e.g., 310) on the heat sink layer.

At block 812, the process deposits an underlayer (e.g., 312 and made of MTO) on the thermal barrier layer. At block 814, the process deposits a first nucleation layer (e.g., 314 and made of FePt—Ag-oxide) using N2 sputter gas on the underlayer. At block 816, the process deposits a second nucleation layer (e.g., 316 and made of FePt—Ag-oxide/nitride) using Ar gas on the first nucleation layer. At block 818, the process deposits one or more magnetic recording layers (MRLs, e.g., 318, 320, 322 and made of FePt—X) on the second nucleation layer. In one aspect, at block 818, the process deposits exactly three MRLs (MRLs, e.g., 318, 320, 322 and made of FePt—X). At block 820, the process deposits a capping layer (e.g., 324) on the one or more MRLs. At block 822, the process deposits an overcoat layer (e.g., 326) on the capping layer. At block 824, the process deposits a lubricant layer (e.g., 328) on the overcoat layer.

In one aspect, the process may refrain from depositing all of the layers noted in process 800, depending on the media design and target application.

Note that the terms “above,” “below,” “on,” and “between” as used herein refer to a relative position of one layer with respect to other layers. As such, one layer deposited or disposed on, above, or below another layer may be directly in contact with the other layer or may have one or more intervening layers. Moreover, one layer deposited or disposed between layers may be directly in contact with the layers or may have one or more intervening layers.

Insofar as the processes described herein are concerned, the processes can in some cases perform the sequence of actions in a different order. In another aspect, the process can skip one or more of the actions. In other aspects, one or more of the actions are performed simultaneously. In some aspects, additional actions can be performed. Unless otherwise indicated, the deposition of (or providing of) at least some of the layers can be performed using any of a variety of deposition processes or sub-processes, including, but not limited to physical vapor deposition (PVD), sputter deposition and ion beam deposition, plasma enhanced chemical vapor deposition (PECVD) and other forms of chemical vapor deposition (CVD), low pressure chemical vapor deposition (LPCVD) and atomic layer chemical vapor deposition (ALCVD). In other aspects, other suitable deposition techniques known in the art might also be used.

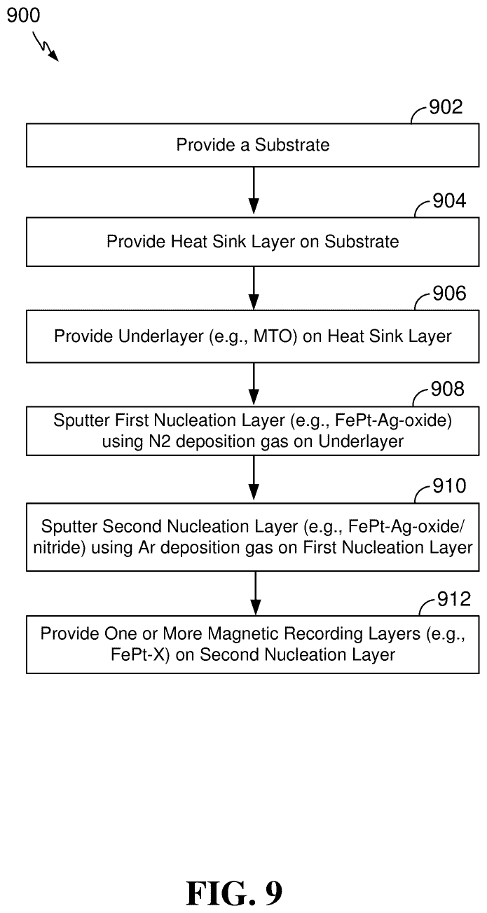

FIG. 9 is a flowchart of another exemplary process 900 for fabricating a HAMR medium that includes small magnetic recording grains with a high aspect ratio, in accordance with an aspect of the disclosure. In one aspect, the process 900 can be used to fabricate, in whole or in part, any of the HAMR media described above, including, for example, HAMR mediums 102, 300, 404, and 600.

At block 902, the process provides a substrate (e.g., 302). At block 904, the process provides a heat sink layer (e.g., 308) on the substrate. At block 906, the process provides an underlayer layer (e.g., 312) on the heat sink layer. At block 908, the process deposits (e.g., using sputter deposition) a first nucleation layer (e.g., 314 and made of FePt—Ag-oxide) using N2 sputter gas on the underlayer. At block 910, the process deposits (e.g., using sputter deposition) a second nucleation layer (e.g., 316 and made of FePt—Ag-oxide/nitride) using Ar gas on the first nucleation layer. At block 912, the process provides one or more magnetic recording layers (MRLs, e.g., 318, 320, 322 and made of FePt—X) on the second nucleation layer. In one aspect, at block 912, the process provides exactly three MRLs (MRLs, e.g., 318, 320, 322 and made of FePt—X).

In one aspect, the process also provides a capping layer (e.g., 324) on the one or more MRLs. In one aspect, the process also provides an overcoat layer (e.g., 326) on the capping layer. In one aspect, the process also provides a lubricant layer (e.g., 328) on the overcoat layer.

As to the sputter deposition of various layers, such as the first nucleation layer (M0-1) of FIGS. 3, 4b, 4c, and 6-9, and while not bound by any particular theory, the inventors have discovered that nitrogen (N2) gas is not as effective as other sputter deposition gases, such as Argon (Ar), and thus is not commonly used for sputtering the magnetic recording layer(s) of HAMR media. When the magnetic recording layer is sputtered with N2 gas, nitride can be undesirably formed. More specifically, N2 sputter gas may react with the Fe element in FePt hard magnetic materials during the sputtering process to form FeN which has soft magnetic properties. Soft magnetic materials cannot be used in a hard magnetic recording layer to keep the magnetization in the easy axis direction to record a “1” or “0”. When this happens, the high anisotropy FePt L10 structure of the recording layer (e.g., for media configured for HAMR) will be ruined, causing degraded magnetic anisotropy and poor magnetic recording performance. Thus, digital information cannot be correctly stored in the magnetic recording layer. Empirical results have confirmed that the recording performance of the media is reduced when one or more FePt magnetic recording layers is deposited with N2 sputter deposition gas. However, as discussed above, the inventors have unexpectedly found that when N2 sputter deposition gas (e.g., pure or substantially pure N2) is used to deposit the first nucleation layer (e.g., on the MTO underlayer), the resulting magnetic media has improved performance characteristics, suggesting that the recording performance of the media will also be improved. The N2 can react and/or bond with the Ti from the seed underlayer to form TiN (e.g., an interfacial layer made of TiN). The improved performance characteristics include smaller diameter grains (e.g., roughly 17% reduction) than comparative recording media. More specifically, the diameter of the grains is reduced by about 17% and the aspect ratio is increased by about 14.7%. As a result, the areal density is expected to be increased accordingly.

Note that the terms “above,” “below,” “on,” and “between” as used herein refer to a relative position of one layer with respect to other layers. As such, one layer deposited or disposed on, above, or below another layer may be directly in contact with the other layer or may have one or more intervening layers. Moreover, one layer deposited or disposed between layers may be directly in contact with the layers or may have one or more intervening layers.

Insofar as the processes described herein are concerned, the processes can in some cases perform the sequence of actions in a different order. In another aspect, the process can skip one or more of the actions. In other aspects, one or more of the actions are performed simultaneously. In some aspects, additional actions can be performed. Unless otherwise indicated, the deposition of (or providing of) at least some of the layers can be performed using any of a variety of deposition processes or sub-processes, including, but not limited to physical vapor deposition (PVD), sputter deposition and ion beam deposition, plasma enhanced chemical vapor deposition (PECVD) and other forms of chemical vapor deposition (CVD), low pressure chemical vapor deposition (LPCVD) and atomic layer chemical vapor deposition (ALCVD). In other aspects, other suitable deposition techniques known in the art might also be used.

### ADDITIONAL ASPECTS

The examples set forth herein are provided to illustrate certain concepts of the disclosure. The apparatuses, devices, or components illustrated above may be configured to perform one or more of the methods, features, or steps described herein. Those of ordinary skill in the art will comprehend that these are merely illustrative in nature, and other examples may fall within the scope of the disclosure and the appended claims. Based on the teachings herein those skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein.

Aspects of the present disclosure have been described above with reference to schematic flowchart diagrams and/or schematic block diagrams of methods, apparatuses, systems, and computer program products according to aspects of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

The subject matter described herein may be implemented in hardware, software, firmware, or any combination thereof. As such, the terms “function,” “module,” and the like as used herein may refer to hardware, which may also include software and/or firmware components, for implementing the feature being described. In one example implementation, the subject matter described herein may be implemented using a computer readable medium having stored thereon computer executable instructions that when executed by a computer (e.g., a processor) control the computer to perform the functionality described herein. Examples of computer-readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding aspects. For instance, an arrow may indicate a waiting or monitoring period of unspecified duration between enumerated steps of the depicted aspect.

The various features and processes described above may be used independently of one another, or may be combined in various ways. All possible combinations and sub-combinations are intended to fall within the scope of this disclosure. In addition, certain method, event, state or process blocks may be omitted in some implementations. The methods and processes described herein are also not limited to any particular sequence, and the blocks or states relating thereto can be performed in other sequences that are appropriate. For example, described tasks or events may be performed in an order other than that specifically disclosed, or multiple may be combined in a single block or state. The example tasks or events may be performed in serial, in parallel, or in some other suitable manner. Tasks or events may be added to or removed from the disclosed example aspects. The example systems and components described herein may be configured differently than described. For example, elements may be added to, removed from, or rearranged compared to the disclosed example aspects.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The word “exemplary” is used herein to mean “serving as an example, instance, or illustration.” Any aspect described herein as “exemplary” is not necessarily to be construed as preferred or advantageous over other aspects. Likewise, the term “aspects” does not require that all aspects include the discussed feature, advantage or mode of operation. The term “coupled” is used herein to refer to the direct or indirect coupling between two objects. For example, if object A physically touches object B, and object B touches object C, then objects A and C may still be considered coupled to one another-even if they do not directly physically touch each other. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X’”, or “approximately value X”, as used in the disclosure shall mean within 10 percent of the ‘value X’. For example, a value of about 1 or approximately 1, would mean a value in a range of 0.9-1.1. In one aspect, “about” as used herein may instead mean 5 percent. In the disclosure various ranges in values may be specified, described and/or claimed. It is noted that any time a range is specified, described and/or claimed in the specification and/or claim, it is meant to include the endpoints (at least in one embodiment). In another embodiment, the range may not include the endpoints of the range.

As used herein, the term percent (%), where the unit is not specified, can be any one of weight %, atomic %, mole %, mass % or volume %.

While the above descriptions contain many specific aspects of the invention, these should not be construed as limitations on the scope of the invention, but rather as examples of specific aspects thereof. Accordingly, the scope of the invention should be determined not by the aspects illustrated, but by the appended claims and their equivalents. Moreover, reference throughout this specification to “one aspect,” “an aspect,” or similar language means that a particular feature, structure, or characteristic described in connection with the aspect is included in at least one aspect of the present disclosure. Thus, appearances of the phrases “in one aspect,” “in an aspect,” and similar language throughout this specification may, but do not necessarily, all refer to the same aspect, but mean “one or more but not all aspects” unless expressly specified otherwise.

The terminology used herein is for the purpose of describing particular embodiments only and is not intended to be limiting of the embodiments. As used herein, the singular forms “a,” “an” and “the” are intended to include the plural forms as well (i.e., one or more), unless the context clearly indicates otherwise. An enumerated listing of items does not imply that any or all of the items are mutually exclusive and/or mutually inclusive, unless expressly specified otherwise. It will be further understood that the terms “comprises,” “comprising,” “includes” “including,” “having,” and variations thereof when used herein mean “including but not limited to” unless expressly specified otherwise. That is, these terms may specify the presence of stated features, integers, steps, operations, elements, materials, or components, but do not preclude the presence or addition of one or more other features, integers, steps, operations, elements, materials, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise. It is also understood that the symbol “/” between two adjacent words has the same meaning as “or” unless expressly stated otherwise. Moreover, phrases such as “connected to,” “coupled to” or “in communication with” are not limited to direct connections unless expressly stated otherwise.

Various components described in this specification may be described as “including” or made of certain materials or compositions of materials. In one aspect, this can mean that the component consists of the particular material(s). In another aspect, this can mean that the component comprises the particular material(s).

Any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be used there or that the first element must precede the second element in some manner. Also, unless stated otherwise a set of elements may include one or more elements. In addition, terminology of the form “at least one of a, b, or c” or “a, b, c, or any combination thereof” used in the description or the claims means “a or b or c or any combination of these elements.” For example, this terminology may include a, or b, or c, or a and b, or a and c, or a and b and c, or 2a, or 2b, or 2c, or 2a and b, and so on.

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

What is claimed is:

1. A magnetic recording medium comprising:
a substrate;
a heat sink layer on the substrate;
an underlayer comprising MgO—TiO on the heat sink layer;
an interfacial layer comprising TiN on the underlayer;
a first nucleation layer on the interfacial layer and comprising FePt—Ag—X, wherein X is an oxide;
a second nucleation layer on the first nucleation layer and comprising FePt—Ag—Y, wherein Y is an oxide or a nitride; and
a magnetic recording layer on the second nucleation layer.

2. The magnetic recording medium of claim 1, wherein the TiN of the interfacial layer is formed of Ti from the underlayer and N2 during sputtering of the first nucleation layer.

3. The magnetic recording medium of claim 1, wherein Y is an oxide.

4. The magnetic recording medium of claim 3, wherein Y comprises at least one of SiO2, TiO2, Cr2O3, ZrO2, Al2O3, Fe2O3, or Ta2O5.

5. The magnetic recording medium of claim 1, wherein Y is SiO2 and X is SiO2.

6. The magnetic recording medium of claim 1, wherein Y is a nitride.

7. The magnetic recording medium of claim 6, wherein Y comprises at least one of Si3N4, TiN, CrN, TaN, ZrN, or VN.

8. The magnetic recording medium of claim 1, wherein a mole percent of Ag in the second nucleation layer is in the range of 0.1 to 12.

9. The magnetic recording medium of claim 1, wherein the first nucleation layer comprises N.

10. The magnetic recording medium of claim 1, wherein:
the interfacial layer is directly on the underlayer;
the first nucleation layer is directly on the interfacial layer;
the second nucleation layer is directly on the first nucleation layer; and
the magnetic recording layer is directly on the second nucleation layer.

11. A magnetic recording medium comprising:
a substrate;
a heat sink layer on the substrate;
a underlayer on the heat sink layer and comprising MgO—TiO (MTO) and TiN;
a first nucleation layer on the underlayer and comprising FePt—Ag—X, wherein X is an oxide;
a second nucleation layer on the first nucleation layer and comprising FePt—Ag—Y, wherein Y is an oxide or a nitride; and
a magnetic recording layer on the second nucleation layer,
wherein the underlayer comprises a first surface and a second surface closer to the first nucleation layer than the first surface; and
wherein a concentration of the TiN in the underlayer is higher at the second surface than at the first surface.

12. The magnetic recording medium of claim 11, wherein the TiN of the underlayer is formed of Ti from the MTO and N gas used during sputtering of the first nucleation layer.

13. The magnetic recording medium of claim 11, wherein Y is an oxide.

14. The magnetic recording medium of claim 13, wherein Y comprises at least one of SiO2, TiO2, Cr2O3, ZrO2, Al2O3, Fe2O3, or Ta2O5.

15. The magnetic recording medium of claim 11, wherein Y is SiO2 and X is SiO2.

16. The magnetic recording medium of claim 11, wherein Y is a nitride.

17. The magnetic recording medium of claim 16, wherein Y comprises at least one of Si3N4, TiN, CrN, TaN, ZrN, or VN.

18. The magnetic recording medium of claim 11, wherein a mole percent of Ag in the second nucleation layer is in the range of 0.1 to 12.

19. The magnetic recording medium of claim 11, wherein the first nucleation layer comprises N2.

20. The magnetic recording medium of claim 11, further comprising:
a thermal barrier layer directly on the heat sink layer;
wherein the underlayer is directly on the thermal barrier layer;
wherein the first nucleation layer is directly on the underlayer;
wherein the second nucleation layer is directly on the first nucleation layer; and
wherein the magnetic recording layer is directly on the second nucleation layer.

21. A method for fabricating a magnetic recording medium, the method comprising:
providing a substrate;
providing a heat sink layer on the substrate;
providing an underlayer comprising MgO—TiO (MTO) on the heat sink layer;
sputtering a first nucleation layer, comprising FePt—Ag—X where X is an oxide, on the underlayer using a N2 deposition gas, wherein N2 from the N2 deposition gas and Ti from the MTO of the underlayer form TiN;
sputtering a second nucleation layer, comprising FePt—Ag—Y where Y is an oxide or a nitride, on the first nucleation layer; and
providing a magnetic recording layer on the second nucleation layer.

22. The method of claim 21, wherein the TiN forms a layer between the underlayer and the first nucleation layer.

23. The method of claim 21:
wherein the underlayer comprises a first surface and a second surface closer to the first nucleation layer than the first surface; and
wherein the TiN forms such that a concentration of the TiN is higher at the second surface than at the first surface.

24. The method of claim 21, wherein Y is SiO2 and X is SiO2.

25. The method of claim 21, wherein the second nucleation layer is sputtered using an Ar deposition gas.

26. A magnetic recording medium formed using a process comprising:
providing a substrate;
providing a heat sink layer on the substrate;
providing an underlayer comprising MgO—TiO (MTO) on the heat sink layer;
sputtering a first nucleation layer, comprising FePt—Ag—X where X is an oxide, on the underlayer using a N2 deposition gas, wherein N2 from the N2 deposition gas and Ti from the MTO of the underlayer form TiN;
sputtering a second nucleation layer, comprising FePt—Ag—Y where Y is an oxide or a nitride, on the first nucleation layer; and
providing a magnetic recording layer on the second nucleation layer.

27. The magnetic recording medium formed using the process of claim 26, wherein the TiN forms a layer between the underlayer and the first nucleation layer.
